(19) United States
(12) Patent Application Publication
(10) Pub. No.: US 2020/0025847 A1
(43) Pub. Date: Jan. 23, 2020

(54) LOCAL COIL DEVICE

(71) Applicant: SAMSUNG ELECTRONICS CO., LTD., Suwon-si (KR)

(72) Inventor: George VERGHESE, Yongin-si (KR)

(73) Assignee: SAMSUNG ELECTRONICS CO., LTD., Suwon-si (KR)

(21) Appl. No.: 16/337,966

(22) PCT Filed: Sep. 20, 2017
(86) PCT No.: PCT/KR2017/010323

§ 371 Date: Mar. 29, 2019

(30) Foreign Application Priority Data
Sep. 29, 2016 (KR) 10-2016-0125223

(51) Int. Cl. G01R 33/34; G01R 19/00; H01C 7/00; G01R 33/422

(52) U.S. Cl. CPC G01R 33/34007; G01R 33/422; H01C 7/008; G01R 19/0084

(57) ABSTRACT

A local coil device includes one or more radio frequency (RF) receive coils; and a signal transceiver implemented to couple a scanner configured to transmit or receive an RF signal and a controller configured to control the local coil device, wherein the RF receive coil comprises a decoupling circuit configured to block an induced current flowing in the RF receive coil when an RF transmission operation of the scanner is performed; and a thermistor having a resistance value changing by the induced current, and wherein the decoupling circuit is configured to block the induced current flowing in the RF receive coil based on a control signal received from the controller through the signal transceiver.

### TECHNICAL FIELD

The disclosure relates to a local coil device.

### BACKGROUND ART

Magnetic resonant imaging devices occupy a key position in the field of diagnostics using medical images because their image capturing requirements are relatively unrestrained and they provide good soft-tissue contrast and various diagnostic information images.

Magnetic Resonance Imaging (MRI) uses magnetic fields that are harmless to the human body and non-ionizing radiation radio frequencies (RFs) to cause nuclear magnetic resonance effects to hydrogen nuclei in a body, thereby imaging the density and physicochemical properties of the nuclei.

The MRI includes an RF transmit coil for sending RF pulses and an RF receive coil for receiving electromagnetic waves emitted by excited atomic nuclei, i.e., magnetic resonance (MR) signals.

Furthermore, the MRI may receive an MR signal excited on an object from a local coil device, which plays an assistant role for the MRI as an external device independent from the MRI and includes a number of RF receive coils.

### DISCLOSURE

### Technical Problem

An embodiment of the disclosure provides a local coil device including a radio frequency (RF) receive coil that reduces latent heat or electromagnetic waves that may be produced by an induced current flowing in a circuit while an RF transmission operation is performed.

### Technical Solution

According to an aspect of the disclosure, a local coil device includes one or more radio frequency (RF) receive coils; and a signal transceiver implemented to couple a scanner configured to transmit or receive an RF signal and a controller configured to control the local coil device, wherein the RF receive coil comprises a decoupling circuit configured to block an induced current flowing in the RF receive coil when an RF transmission operation of the scanner is performed; and a thermistor having a resistance value changing by the induced current, and wherein the decoupling circuit is configured to block the induced current flowing in the RF receive coil based on a control signal received from the controller through the signal transceiver.

The thermistor may have a resistance value that increases as the induced current increases.

The thermistor may have a resistance value that increases at a preset temperature.

The decoupling circuit may reduce the induced current by increasing impedance of the RF receive coil when the RF transmission operation is performed.

The decoupling circuit may reduce impedance of the RF receive coil when an RF reception operation of the RF receive coil is performed.

The local coil device may further include a voltmeter configured to measure a voltage of the thermistor.

The voltage of the thermistor may be conveyed to the controller through the signal transceiver.

The controller may stop the RF transmission operation of the scanner when the voltage of the thermistor is equal to or greater than a preset threshold.

The decoupling circuit may include a diode and a capacitor connected in parallel.

The diode may be applied with a forward voltage when the RF transmission operation is performed, and a backward voltage when an RF reception operation of the RF receive coil is performed.

The local coil device may further include a voltmeter configured to measure a voltage of the thermistor, wherein the controller may determine whether to stop the RF transmission operation based on the voltage of the thermistor.

### Advantageous Effects

As is apparent from the above, even while a radio frequency (RF) transmission operation is performed by a Magnetic Resonance Imaging (MRI) system in a state where an object is adjacent to an RF receive coil or a local coil device having the same, damage to the object by latent heat or electromagnetic waves produced by the RF receive coil or the local coil device having the same may be reduced.

### DESCRIPTION OF DRAWINGS

FIG. 1 is a schematic diagram of a Magnetic Resonance Imaging (MRI) system;

FIGS. 2 to 4 are exterior views of local coil devices, according to various embodiments;

FIG. 5 is a circuit diagram of a radio frequency (RF) receive coil included in a local coil device, according to an embodiment;

FIG. 6 shows circuit diagrams of a decoupling circuit included in an RF receive coil;

FIG. 7 is a frequency-impedance response graph of a decoupling circuit;

FIG. 8 is a circuit diagram of an RF receive coil, according to another embodiment; and

FIG. 9 is a flowchart of a control method of a local coil device, according to an embodiment.

### MODES OF THE INVENTION

Like reference numerals refer to like elements throughout the specification. The specification does not explain all the elements of embodiments, and descriptions common in the art the disclosure pertains to or overlapping descriptions among the embodiments will be omitted.

The term ‘unit’, ‘module’, ‘member’, or ‘block’ may be implemented in software or hardware, and in some embodiments, a plurality of ‘units’, ‘modules’, ‘members’, or ‘blocks’ may be implemented in a single element, or a single ‘unit’, ‘module’, ‘member’, or ‘block’ may include a plurality of elements.

Throughout the specification, the term ‘including’ or ‘comprising’ is inclusive or open-ended and does not exclude additional, unrecited elements or method steps, unless otherwise mentioned.

An ordinal number like “first” or “second” may be used to tell a component from another, but the component is not limited by the number.

The singular expressions may include plural expressions unless the context clearly dictates otherwise.

Throughout the specification, the term ‘image’ may refer to multi-dimensional data including discrete image elements (e.g., pixels in a two dimensional (2D) image and voxels in a three dimensional (3D) image). For example, the image may include a medical image of an object, which is obtained by an X-ray, computerized tomography (CT), Magnetic Resonance Imaging (MRI), ultrasound, or other medical imaging system.

Throughout the specification, the term ‘object’ may include a person or animal, or part of the person or animal. For example, the object may include an organ such as skins, a liver, a heart, a uterus, a brain, a breast, an abdomen, etc., or blood vessels. Furthermore, the object may include a phantom. The phantom refers to a substance having a volume closely approximate to an effective atomic number and density of a living creature, and may include a spherical phantom having a similar nature to a human body.

In addition, throughout the specification, the term ‘user’ is an expert in medicine, which may be a doctor, a nurse, a medical technologist, a medical image specialist, and a technician who fixes the medical system, without being limited thereto.

A Magnetic Resonance Imaging (MRI) system refers to a system that obtains magnetic resonance (MR) signals and reconstructs the MR signals to an image. The MR signal refers to a radio frequency (RF) signal emitted from the object.

The MRI system has a main magnet to produce a static magnetic field and arrange magnetic dipole moments of particular atomic nuclei of an object located in the static magnetic field in a direction of the static magnetic field. A gradient coil may apply a gradient signal to the static magnetic field to produce a gradient field, inducing a different resonance frequency for each part of the object.

An RF coil may irradiate an RF signal tuned to the resonance frequency of a part whose image to be obtained is desired. Furthermore, as the gradient field is formed, the RF coil may receive MR signals with different resonance frequencies emitted from different parts of the object. Through this phase, the MRI system obtains an image from the MR signals using an image restoration scheme.

The working principle and embodiments of the disclosure will now be described with reference to accompanying drawings.

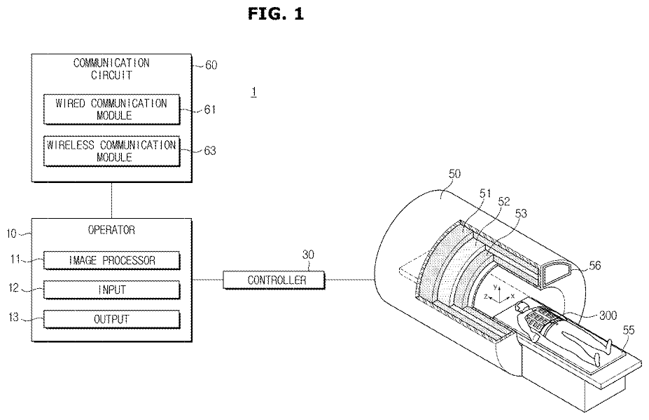

FIG. 1 is a schematic diagram of an MRI system. Referring to FIG. 1, an MRI system 1 may include an operator 10, a controller 30, and a scanner 50. The controller 30 as herein used may be implemented independently, as described in FIG. 1. Alternatively, the controller 30 may be divided into a plurality of parts, which may be included in the respective components of the MRI system 1. The components will now be described in detail.

The scanner 50 may be implemented in a form with an empty internal space to which an object may be inserted (e.g., a bore form). In the internal space of the scanner 50, a static magnetic field and a gradient field are produced and an RF signal is irradiated.

The scanner 50 may include a static magnetic field producer 51, a gradient field producer 52, an RF coil 53, a table 55, and a display 56. The static magnetic field producer 51 produces a static magnetic field to arrange magnetic dipole moments of atomic nuclei included in the object in the static magnetic field. The static magnetic field producer 51 may be implemented with a permanent magnet or a superconductive magnet with a cooling coil.

The gradient field producer 52 is coupled to the controller 30. It produces a gradient field by applying a gradient to the static field based on a control signal received from the controller 30. The gradient field producer 52 includes X, Y, and Z coils to produce gradient fields of X, Y, and Z axes, respectively, which are perpendicular to each other, and generates gradient signals to fit positions to be scanned in order to induce a different resonance frequency for each part of the object.

The RF coil 53 is coupled to the controller 30, and may irradiate an RF signal to the object based on a control signal received from the controller 30 and receive an MR signal emitted from the object. The RF coil 53 may transmit the RF signal to a nucleus, which is precessing, with the same frequency as that of the precession, stop transmitting the RF signal, and receive an MR signal emitted from the object.

The RF coil 53 may be implemented with an RF transmit coil to produce electromagnetic waves with a radio frequency corresponding to the kind of the nucleus and an RF receive coil to receive electromagnetic waves emitted from the nucleus, or with an RF transceiver coil having both transmission/reception functions.

The RF transmit coil may be implemented as a whole-volume coil to transmit RF pulses to the whole object, and the RF receive coil may also be implemented as a whole-volume coil to receive an excited MR signal from the whole object. The whole-volume coil is also referred to as a body coil.

Furthermore, the RF receive coil may be provided in an external device (hereinafter, called a ‘local coil device’ 300), which is separate from the scanner 50, and mounted on the object. The local coil device 300 is coupled to the scanner 50, controller 30, and operator 10 through signal transmission and/or reception entities, such as cables, and transmits data to an image processor 11 on an MR signal produced from the nucleus. The local coil device 300 may use, for example, a head coil, a spine coil, a torso coil, or a knee coil as a separate coil depending on the part to be scanned or mounted.

Accordingly, the local coil device may only serve as an RF receive coil while the body coil may serve as both RF transmit coil and RF receive coil.

The display 56 may be provided on the outer and/or inner side of the scanner 50. The display 56 may be controlled by the controller 30 to provide information relating to the medical image scanning to the user or the object.

Furthermore, the scanner 50 may be provided with an object monitoring information obtainer to obtain and convey monitoring information about a condition of the object. For example, the object monitoring information obtainer (not shown) may obtain monitoring information on the object from a camera (not shown) that captures motion and position of the object, a spirometer (not shown) for measuring respirations of the object, an electrocardiogram (ECG) measurer (not shown) for measuring electrocardiogram of the object, or a thermometer (not shown) for measuring body heat of the object, and convey the monitoring information to the controller 30. The controller 30 may then control operation of the scanner 50 based on the monitoring information about the object. The controller 30 will now be described in detail.

The controller 30 may control general operation of the scanner 50.

The controller 30 may control a sequence of signals produced within the scanner 50. The controller 30 may control the gradient field producer 52 and the RF coil 53 based on a pulse sequence received from or designed by the operator 10.

The pulse sequence may include all information required to control the gradient field producer 52 and the RF coil 53, and for example, include information about an intensity, application duration, and/or application timing of the pulse signal to be applied to the gradient field producer 52.

The controller 30 may control a waveform generator (not shown) that generates gradient waves, i.e., current pulses based on the pulse sequence and a gradient amplifier (not shown) that amplifies and conveys the generated current pulses to the gradient field producer 52, to control production of the gradient field of the gradient filed producer 52.

The controller 30 may control operation of the RF coil 53. For example, the controller 30 may irradiate an RF signal by supplying RF pulses with a resonance frequency to the RF coil 53, and receive an MR signal received by the RF coil 53. In this case, the controller 30 may control operation of a switch (e.g., a T/R switch) that is able to control transmission/reception directions based on a control signal, thereby controlling irradiation of the RF signal and reception of the MR signal based on the operation mode.

The controller 30 may control movement of the table 55 on which the object lies. Before the start of scanning, the controller 30 may move the table 55 in advance to fit for a portion to be scanned of the object.

The controller 30 may control the display 56. For example, the controller 30 may control on/off of the display 56 or screens displayed by the display 56 based on control signals.

The controller 30 may control the local coil device 300. For example, the controller 30 may control operation of a switch (e.g., an on/off switch) that is able to control whether to receive an MR signal based on a control signal, thereby controlling reception of an MR signal of the local coil device 300 based on the operation mode.

The controller 30 may be implemented with a memory (not shown) for storing an algorithm to control operation of the components in the MRI system 1 and data of a program format and a processor (not shown) for performing the aforementioned operation using the data stored in the memory. The memory and the processor may be implemented in separate chips. Alternatively, the memory and the processor may be implemented in a single chip.

The operator 10 may control general operation of the MRI system 1. The operator 10 may include an image processor 11, an input 12, and an output 13.

The image processor 11 may store MR signals received from the controller 30 using the memory and use the processor to apply an image restoration scheme, thereby creating an image of the object from the stored MR signals.

For example, once digital data fills the k-space (also referred to as e.g., Fourier space or frequency space) until k-space data is completed, the image processor 11 applies various image restoration schemes (e.g., an inverse Fourier transform to the k-space data) by means of the processor, to restore the k-space data to an image.

Furthermore, various kinds of signal processing applied to the MR signals by the image processor 11 may be performed in parallel. For example, a plurality of MR signals received by multi-channel RF coils may be processed in parallel and restored to an image. The image processor 11 may store the restored image in the memory, or the controller 30 may store the image in an external server through a communication circuit 60, as will be described later.

The input 12 may receive control commands from the user about general operation of the MRI system 1. For example, the input 12 may receive from the user object information, parameter information, information about scanning conditions, a pulse sequence, and/or the like. The input 12 may be implemented as a keyboard, a mouse, a trackball, a voice recognizer, a gesture recognizer, a touch screen, or the like.

The output 13 may output the image created by the image processor 11. Furthermore, the output 13 may output a User Interface (UI) configured for the user to enter a control command for the MRI system 1. The output 13 may be implemented as a speaker, a printer, a display, or the like, and the display may include the display 56 provided on the outer and/or inner side of the scanner 50 as described above. In the following embodiments, the output 13 is assumed to be implemented as a display, but the embodiments are not limited thereto.

The display may be provided as a Cathode Ray Tube (CRT), a Digital Light Processing (DLP) panel, a Plasma Display Panel (PDP), a Liquid Crystal Display (LCD) panel, an Electro Luminescence (EL) panel, an Electrophoretic Display (EPD) panel, an Electrochromic Display (ECD) panel, a Light Emitting Diode (LED) panel, or Organic Light Emitting Diode (OLED) panel, but is not limited thereto.

Although the operator 10 and the controller 30 are shown in FIG. 1 as separate entities, they may be incorporated in a single device as described above. Furthermore, processes performed by the operator 10 and the controller 30 may be performed in other entities. For example, the image processor 11 may convert the MR signal received from the controller 30 to a digital signal, or the controller 30 may perform the conversion by itself.

At least one component may be added or deleted to correspond to capabilities of the components of the MRI system 1 shown in FIG. 1. Moreover, people having ordinary skill in the art will understand that relative positions of the components may be changed based on the structure or performance of the system.

Each of the components shown in FIG. 1 refers to a software and/or Field Programmable Gage Array (FPGA) or hardware component such as an Application Specific Integrated Circuit.

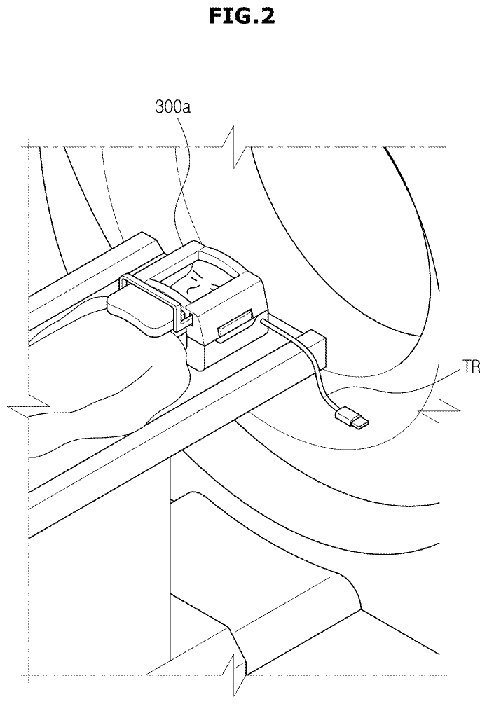

The local coil device 300 according to an embodiment will now be described. An RF receive coil, as will be described below, is assumed to be arranged in the local coil device 300 to receive an excited MR signal from a part of an object. FIGS. 2 to 4 are exterior views of local coil devices, according to various embodiments.

As shown in FIG. 2, the local coil device 300 may be implemented as a head coil device 300a, which scans the head of an object and receives an excited MR signal from the head.

There may be a plurality of RF receive coils provided in the head coil device 300a, and the plurality of RF receive coils may receive an echo signal, i.e., an MR signal, produced from the head of the object and send data on the MR signal to the image processor 11 of the MRI system 1 through a signal transceiver TR such as a cable, to obtain an MR image of the head of the object.

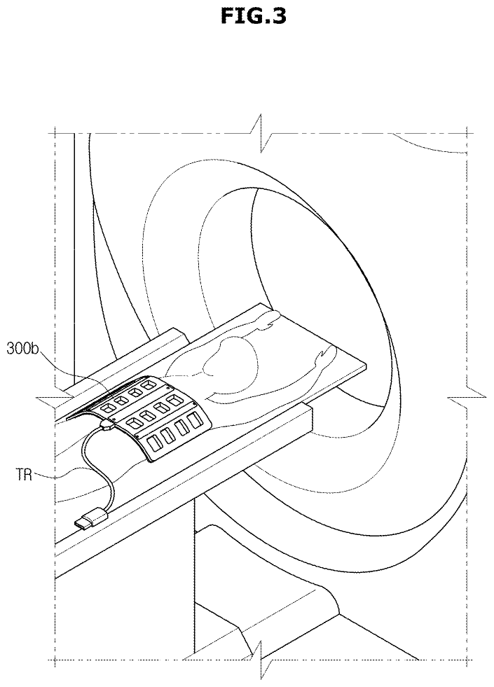

Furthermore, as shown in FIG. 3, the local coil device 300 may be implemented as a torso coil device 300b, which scans the breast or abdomen of an object and receives an excited MR signal from the breast or abdomen.

The torso coil device 300b may also include a plurality of RF receive coils, and the plurality of RF receive coils may receive an echo signal, i.e., an MR signal, produced from the breast or abdomen of the object, thereby obtaining an MR image of the breast or abdomen of the object.

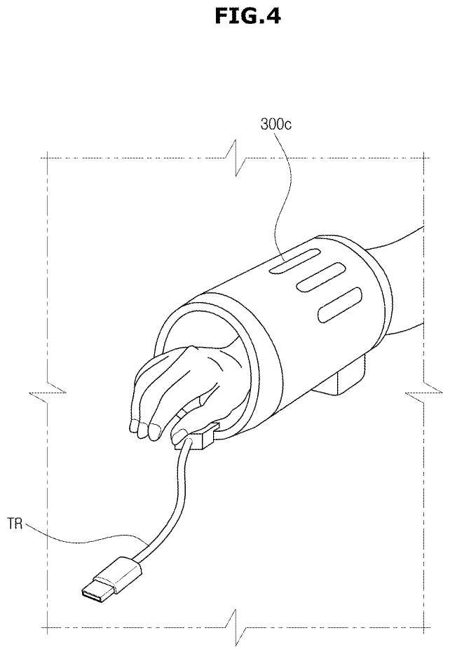

In addition, as shown in FIG. 4, the local coil device 300 may be implemented as a partial coil device 300c, which scans a partial region of an object and receives an excited MR signal from the partial region. The partial region may correspond to an arm, a leg, or any other part of an object.

The partial coil device 300c may also include a plurality of RF receive coils, and the plurality of RF receive coils may receive an echo signal, i.e., an MR signal, produced from the partial region of the object, thereby obtaining an MR image of the partial region of the object.

With the signal transceiver TR such as a cable connecting the local coil device 300 to the MRI system 1, the RF receive coil provided in the local coil device 300 may be electrically coupled to the scanner 50, controller 30, and image processor 11 of the MRI system 1.

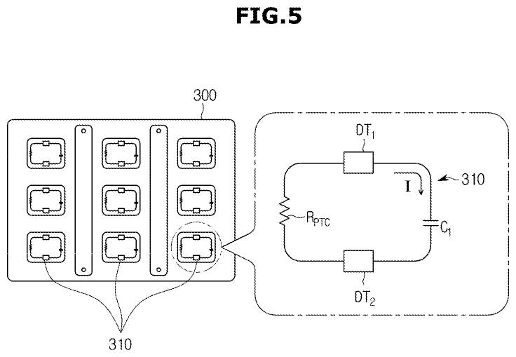

The RF receive coil included in the local coil device 300 according to an embodiment will now be described with reference to FIGS. 5 to 8.

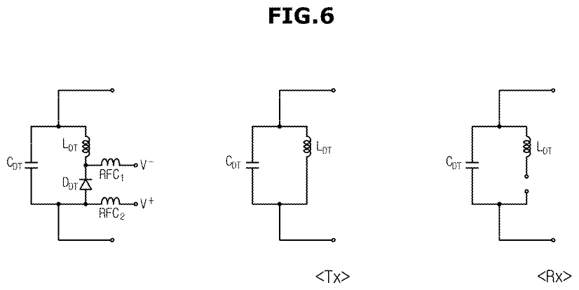

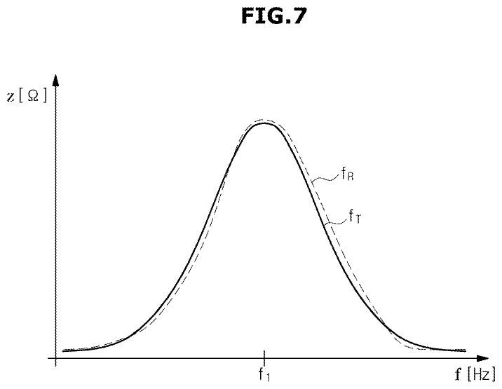

FIG. 5 is a circuit diagram of an RF receive coil included in a local coil device, according to an embodiment, FIG. 6 is a circuit diagram of a decoupling circuit included in the RF receive coil, and FIG. 7 is a frequency-impedance response graph of the decoupling circuit.

As described above, the local coil device according to an embodiment includes a plurality of RF receive coils 310.

The RF receive coil 310 includes one or more capacitors C₁ and one or more decoupling circuits DT1 and DT2 connected in series, the one or more capacitors C₁ and one or more decoupling circuits DT1 and DT2 being connected by wires that serves as inductors (i.e., coils). Although there are two decoupling circuits DT1 and DT2 and one capacitor C1 shown in FIG. 5, the numbers of the decoupling circuits and the capacitors are not limited thereto.

The RF receive coil 310 receives an object-excited MR signal to perform an RF reception operation, in which case due to structural characteristics of the circuit, a current may be induced to the RF receive coil 310 of the local coil device 300 while not the RF reception operation but the RF transmission operation is being performed in the scanner 50.

An induced current I may cause latent heat or electromagnetic waves from the RF receive coil 310, so the object wearing the local coil device 300 including the plurality of RF receive coils 310 may get a burn from the latent heat or electromagnetic waves.

Accordingly, the induced current I needs to be blocked during the RF transmission operation, so that, with the decoupling circuits DT1 and DT2 that serve as variable resistors included in the RF receive coil 310 according to an embodiment, the induced current I flowing in the RF receive coil 310 is controlled.

The decoupling circuits DT1 and DT2 are also called de-tuning circuits, controlling the induced current I to be blocked from flowing in the RF receive coil 310 of the local coil device 300 while an RF transmission operation is performed in the whole-volume coil of the MRI system 1 (i.e., in an RF transmission mode), and control the current I to flow in the RF receive coil 310 of the local coil device 300 while an RF reception operation is performed in the whole-volume coil and the local coil device 300 (i.e., an RF reception mode).

Specifically, the decoupling circuits DT1 and DT2 may control the current I induced to the RF receive coil 310 from irradiation of an RF signal of the whole-volume coil to be blocked by increasing impedance of the RF receive coil 310 while the RF transmission operation is performed in the whole-volume coil of the scanner 50 and control the current I to flow through the RF receive coil 310 by reducing impedance of the RF receive coil 310 of the local coil device 300 while the RF reception operation is performed in the whole-volume coil of the scanner 50 and the local coil device 300. While the RF reception operation is performed, a voltage across the capacitor C1 or a voltage across one of the decoupling circuits DT1 and DT2 may be conveyed as an output signal to the controller 30 and image processor 11 of the MRI system 1.

A decoupling circuit DT of FIG. 6 represents at least one of the decoupling circuits DT1 and DT2 of FIG. 5. Referring to FIG. 6, the decoupling circuit DT according to an embodiment includes a diode D_{DT} and an inductor L_{DT}, which are connected in series, and a capacitor C_{DT} connected in parallel with the diode and D_{DT} and the inductor L_{DT} connected in series. In this case, the decoupling circuit DT may be connected in series with other elements that constitute the RF receive coil 310.

The diode D_{DT} includes a PIN diode.

The anode of the diode D_{DT} is connected to the positive terminal of a power source that supplies a voltage to the circuit. Accordingly, a forward voltage may be applied to the diode D_{DT} with the anode supplied with voltage +V and the cathode supplied with voltage −V, and a backward voltage may be applied to the diode D_{DT} with the anode supplied with voltage −V and the cathode supplied with voltage +V.

The voltage applied to the diode D_{DT} may vary based on the control signal. The control signal may be a signal received from the controller 30 of the MRI system 1, or may be a signal received from a separate controller (not shown) embedded in the local coil device 300. The controller embedded in the local coil device 300 may include a memory that stores a program and data to determine whether to apply a forward voltage or a backward voltage depending on whether it is the RF transmission mode or the RF reception mode, and a processor that performs the respective functions based on the program and data stored in the memory.

With the forward voltage applied to diode D_{DT} from the power source, the current may flow from the bottom to the top of diode D_{DT} shown in FIG. 6.

In the RF transmission mode (Tx), the forward voltage may be applied, so the current flows through the diode D_{DT}. For example, a voltage may be applied such that 100 mA flows through the diode D_{DT}. As the current flows through the diode D_{DT}, the diode D_{DT} may be represented by an equivalent circuit having a small resistance value as good as the diode D_{DT} is short-circuited. For example, the small resistance value may be 0.5 ohm.

In the RF transmission mode (Tx), the short-circuited diode D_{DT} makes the inductor L_{DT} and capacitor C_{DT} form a parallel resonance circuit. Accordingly, the capacitor C_{DT} is in a high impedance state and in a decoupling state of not magnetically coupling with other elements of the RF receive coil 310.

Therefore, when RF pulses tuned to a frequency (e.g., a Larmor frequency as high as 42.68 MH or 123.48 MHz) are applied to the object from the RF transmit coil of the MRI system 1 in the RF transmission mode (Tx), an induced current may rarely flow in the local coil device 300 and thus the latent heat due to the induced current may not be generated due to the decoupling state of the RF receive coil 310.

On the other hand, in the RF reception mode (Rx), a backward voltage or no voltage is applied to the diode D_{DT}. Hence, a current rarely flows in the diode D_{DT}, and most of the current flows in the capacitor C_{DT} connected in parallel with the diode D_{DT}. Because no current flows in the diode D_{DT}, the diode D_{DT} may be represented by an equivalent circuit having a high resistance value as good as the diode D_{DT} is opened. For example, the high resistance value may be 50 kΩ.

In the RF reception mode (Rx), a signal may be extracted from across the capacitor C_{DT} of the decoupling circuit DT or from across any capacitor C1 of the RF receive coil 310, and the extracted signal may be sent to the controller 30 and image processor 11 of the MRI system 1.

In the RF reception mode (Rx), a signal needs to be collected at the same frequency as that of the RF pulses applied to the object in the RF transmission mode (Tx). In other words, as in FIG. 7, a signal is collected in the same frequency band f_{R} as an RF transmission frequency band f_{T} having a center frequency f₁. In the case that the signal is collected in the same frequency band f_{R} as the RF transmission frequency band f_{T}, the decoupling circuit DT is in a high impedance Z₀ state and in the decoupling state where the induced current rarely flows.

Even with the inclusion of the decoupling circuit DT, an induced current to the RF receive coil 310 of the local coil device 300 may still be caused by a device fault in the decoupling circuit DT or an error in setting the center frequency, and the induced current may cause a rise in the temperature of the local coil device 300 and thus the latent heat or electromagnetic waves may still be detected. Accordingly, a component to complement the decoupling circuit DT is required in the local coil device 300.

For this, the RF receive coil 310 according to an embodiment further includes a thermistor R_{PTC} to block the induced current.

The thermistor R_{PTC} may include at least one of a positive temperature coefficient (PTC) thermistor that blocks the current when its resistance increases as the current increases or a critical temperature resistor (CIR) thermistor that blocks the current when its resistance changes rapidly at a preset temperature.

When the thermistor R_{PTC} is implemented with the PTC thermistor, the impedance of the RF receive coil 310 increases dramatically when the temperature of the PTC thermistor rises as the current flowing in the RF receive coil 310 increases. The current flowing in the RF receive coil 310 is almost blocked as the impedance increases, which may, accordingly, reduce the latent heat or electromagnetic waves produced from the RF receive coil 310. In this case, the thermistor R_{PTC} may reduce the Specific Absorption Rate (SAR) to a reference value or less that satisfies the International Electro technical Commission (IEC) standard (e.g., IEC60601-1).

When the thermistor R_{PTC} is implemented with the CIR thermistor, the impedance of the RF receive coil 310 increases dramatically and the current flowing in the RF receive coil 310 is almost blocked as the temperature of the CIR thermistor reaches a preset threshold. Accordingly, the latent heat or electromagnetic waves produced from the RF receive coil 310 may be reduced. Even in this case, the thermistor R_{PTC} may reduce the SAR to a reference value or less that satisfies the IEC standard (e.g., IEC60601-1).

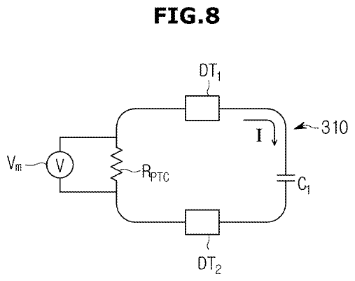

In the meantime, the RF receive coil 310 according to another embodiment may further include a voltmeter for measuring the voltage of the thermistor R_{PTC}. FIG. 8 is a circuit diagram of an RF receive coil, according to another embodiment.

Referring to FIG. 8, a voltmeter Vm connected in parallel with the thermistor R_{PTC} measures and conveys the voltage across the thermistor R_{PTC} to a controller. The controller may be the controller 30 of the MRI system 1 or a controller built in the local coil device 300. In the following description, the controller is assumed to be the controller 30 of the MRI system 1 for the convenience of explanation.

As the voltage across the thermistor R_{PTC} measured by the voltmeter Vm is proportional to the impedance of the thermistor R_{PTC}, the controller 30 may estimate the induced current of the RF receive coil 310 indirectly by measuring the voltage of the thermistor R_{PTC} and thus control the latent heat or electromagnetic waves produced from the RF receive coil 310.

For this, the controller 30 determines whether the voltage of the thermistor R_{PTC} measured by the voltmeter Vm is equal to or greater than a preset threshold, and when the voltage of the thermistor R_{PTC} measured by the voltmeter Vm is equal to or greater than the preset threshold, stops the RF transmission operation of the scanner 50 of the MRI system 1. With the stoppage of the RF transmission operation of the scanner 50, the induced current to the RF receive coil 310 may not be caused any longer, thereby overcoming the problem of the latent heat or electromagnetic waves due to the object wearing the local coil device 300.

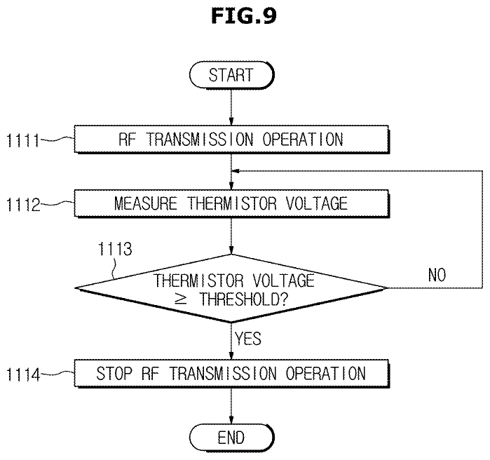

A control method of the local coil device 300 according to an embodiment will now be described with reference to FIG. 9. FIG. 9 is a flowchart of a control method of a local coil device according to an embodiment, which will be described in conjunction with the RF receive coil 310 as described above in connection with FIG. 8.

First, the controller 30 of the MRI system 1 controls the RF transmit coil, i.e., the scanner 50 to irradiate an RF signal in order to perform an RF transmission operation in 1111. A control signal from the controller 30 may be sent to the local coil device 300 through a signal transceiver such as a cable connecting the MRI system 1 to the local coil device 300.

Next, the voltmeter Vm of the RF receive coil 310 included in the local coil device 300 measures the voltage across the thermistor R_{PTC} in 1112, and stops the RF transmission operation in 1114 when the voltage is equal to or greater than a preset threshold (yes in 1113). On the other hand, when the voltage is less than the preset threshold (no in 1113), the RF transmission operation is performed and the voltage of the thermistor is monitored again, in 1112. The voltage value of the thermistor R_{PTC} may be conveyed to the controller 30 of the MRI system 1 through a signal transceiver such as a cable connecting the MRI system 1 to the local coil device 30.

Although the control method of the local coil device 300 according to the embodiment was described as being performed by the controller 30 included in the MRI system 1, the control method of the local coil device 300 may be performed by a controller built in the local coil device 300 in another embodiment.

The control method of the MRI system 1 and local coil device 300 in the embodiment may be implemented in the form of a recording medium that stores instructions that may be carried out by a computer. The instructions may be stored in the form of program codes that, when executed by a processor, may produce program modules to perform the operation according to the embodiments. The recording medium may correspond to a computer-readable recording medium.

The computer-readable recording medium includes all types of recording media having instructions stored therein, that may be interpreted by a computer. For example, it may be a read only memory (ROM), a random access memory (RAM), a magnetic tape, a magnetic disk, a flash memory, an optical data storage device, etc.

The embodiments of the disclosure have thus far been described with reference to accompanying drawings. Several embodiments have been described above, but a person of ordinary skill in the art will understand and appreciate that various modifications can be made without departing the scope of the disclosure. The above embodiments are only by way of example, and should not be interpreted in a limited sense.

1. A local coil device comprising:
one or more radio frequency (RF) receive coils; and
a signal transceiver implemented to couple a scanner configured to transmit or receive an RF signal and a controller configured to control the local coil device,
wherein the RF receive coil comprises,
a decoupling circuit configured to block an induced current flowing in the RF receive coil when an RF transmission operation of the scanner is performed; and
a thermistor having a resistance value changing by the induced current, and
wherein the decoupling circuit is configured to block the induced current flowing in the RF receive coil based on a control signal received from the controller through the signal transceiver.

2. The local coil device of claim 1, wherein the resistance value of the thermistor increases as the induced current increases.

3. The local coil device of claim 1, wherein the resistance value of the thermistor increases at a preset temperature.

4. The local coil device of claim 1, wherein the decoupling circuit is configured to reduce the induced current by increasing impedance of the RF receive coil when the RF transmission operation is performed.

5. The local coil device of claim 1, wherein the decoupling circuit is configured to reduce impedance of the RF receive coil when an RF reception operation of the RF receive coil is performed.

6. The local coil device of claim 1, further comprising a voltmeter configured to measure a voltage of the thermistor.

7. The local coil device of claim 6, wherein the voltage of the thermistor is conveyed to the controller through the signal transceiver.

8. The local coil device of claim 6, wherein the controller is configured to stop the RF transmission operation of the scanner when the voltage of the thermistor is equal to or greater than a preset threshold.

9. The local coil device of claim 1, wherein the decoupling circuit comprises a diode and a capacitor connected in parallel.

10. The local coil device of claim 9, wherein the diode is applied with a forward voltage when the RF transmission operation is performed, and a backward voltage when an RF reception operation of the RF receive coil is performed.

11. The local coil device of claim 1, further comprising a voltmeter configured to measure a voltage of the thermistor,
wherein the controller is configured to determine whether to stop the RF transmission operation based on the voltage of the thermistor.
